(19) United States
(12) Patent Application Publication
(10) Pub. No.: US 2015/0364651 A1
(43) Pub. Date: Dec. 17, 2015

(54) Flip-Chip Light Emitting Diode Assembly With Relief Channel

(71) Applicant: Toshiba Corporation, Tokyo (JP)

(72) Inventors: Wei Zhao, Dublin, CA (US); Chih-Wei Chuang, Albany, CA (US); Chao-Kun Lin, San Jose, CA (US); Kai Liu, Pleasanton, CA (US)

(73) Assignee: TOSHIBA CORPORATION

(21) Appl. No.: 14/303,201

(22) Filed: Jun. 12, 2014

(51) Int. Cl. H01L 33/38; H01L 33/00

(52) U.S. Cl. CPC H01L 33/382; H01L 33/005; H01L 2933/0016

(57) ABSTRACT

A flip-chip LED assembly with relief channel and a method for making the flip-chip LED assembly is disclosed. In one embodiment, the flip-chip LED assembly includes a flip-chip LED with a via and a channel formed in the surface of the flip-chip LED. The channel extends from the via to a sidewall of the flip-chip LED. In another embodiment, a plurality of vias and a plurality of channels are formed in the surface of the flip-chip LED. Each of the plurality of channels extend from each of the vias to another via, or to a sidewall of the flip-chip LED.

### BACKGROUND OF THE INVENTION

A flip-chip LED is formed in a very similar manner as a traditional lateral LED chip. Group III-V compounds (and alloys) such as gallium nitride (GaN), aluminum nitride (AlN), indium nitride (InN), gallium arsenide (GaAs), aluminum arsenide (AlAs), indium arsenide (InAs), gallium phosphide (GaP), indium phosphide (InP), aluminum phosphide (AlP), gallium indium nitride (GaInN), and indium gallium arsenide phosphide (InGaAsP) and Group II-VI compounds (and alloys) such as zinc oxide (ZnO), are epitaxially grown on a semiconductor growth substrate to form the N-type and P-type semiconductor layers of the LED. The epitaxial semiconductor layers may be formed by a number of developed processes including, for example, Liquid Phase Epitaxy (LPE), Molecular-Beam Epitaxy (MBE), and Metal Organic Chemical Vapor Deposition (MOCVD).

For traditional flip-chip LED's, the semiconductor growth substrate typically comprises a transparent material which allows the emitted light to escape. The semiconductor growth substrate can be sapphire (Al₂0₃), glass (SiO₂), gallium nitride (GaN), silicon carbide (SiC), gallium phosphide (GaP), gallium arsenide (GaAs), and indium phosphide (InP). After the epitaxial semiconductor layers are formed, electrodes are electrically coupled to the N-type and P-type semiconductor layers using known photolithography, etching, evaporation, and polishing processes.

A carrier is then bonded to the flip-chip LED. The carrier can be a submount package or a handling wafer. A submount package having an n-contact and a p-contact is bonded to the electrodes of the flip-chip LED, electrically and thermally coupling the flip-chip LED to the submount package. A handling wafer can also be bonded to the flip-chip LED, in place of the submount package. The flip-chip LED and the carrier are bonded using known bonding techniques, including eutectic bonding, intermetallic bonding, adhesive bonding, soldering pastes, etc. Individual devices can be diced from the wafer either before bonding, or after bonding. In the case where the submount package is bonded to the flip-chip LED, unlike the traditional lateral LED, the flip-chip LED is already electrically and thermally coupled to the submount package, and there is no need to separately mount the LED chip to the package with wire bonding.

To further improve the light output efficiency of the flip-chip LED, the semiconductor growth substrate is removed, and the top surface of the LED is roughened by etching. Removal of the semiconductor growth substrate may be accomplished by any known method, including laser lift-off (LLO), mechanical grinding, chemical etching, or any combination thereof. By removing the growth substrate, a non-transparent growth substrate, such as silicon (Si), can be used to grow the semiconductor layers of the LED. By roughening the top surface of the LED, the wave-guiding of the light within the semiconductor layers of the LED are disrupted, leading to more light emission through the top surface and increasing light output. This improved flip-chip LED structure is commonly referred to as a thin-film flip-chip LED.

Another improvement to the flip-chip LED is shown in FIGS. 1A and 1B, which is described in U.S. Pat. No. 7,652,304 (“Steigerwald”). FIG. 1A is a plan view of the flip-chip LED 100 without the submount package, according to Steigerwald. In FIG. 1A, a plurality of vias 112 are formed in the upper semiconductor layer of the flip-chip LED 100. Each of the vias 112 are completely surrounded by the upper semiconductor layer of the flip-chip LED 100, and extend down to the lower semiconductor layer.

FIG. 1B is a corresponding cross-sectional view of the flip-chip LED 100 along axis AA shown in FIG. 1A. By forming a plurality of vias 112 in the surface of the LED down to a first semiconductor layer 104 and depositing a plurality of second electrodes 116 at the bottom of each of the vias 112, the flip-chip LED assembly disclosed by Steigerwald allows for a short lateral current spreading through the first and second semiconductor layers, reducing the series resistance of the device, reducing the amount of voltage required to drive the LED and improving light output efficiency. However, because the plurality of vias 112 are completely surrounded by a first electrode 110, a second semiconductor layer 108, and a light emitting layer 106, when carrier 122 is bonded to the flip-chip LED 100 there is a high probability that air and bonding flux will become trapped inside the vias 112.

Trapped air and bonding flux inside the vias 112 will have a negative effect on the bonding strength between the carrier 112 and the flip-chip LED 100, introducing localized mechanical stress at each of the vias 112. Additionally, the trapped air and bonding flux will degrade the thermal and electrical connection between the carrier 112 and the flip-chip LED 100. In extreme cases, the weakened bond between the carrier 112 and flip-chip LED 100 may result in delamination or cracking of the flip-chip LED 100. In short, the overall reliability and performance of the flip-chip LED assembly disclosed by Stiegerwald is reduced.

### BRIEF DESCRIPTION OF THE INVENTION

In one embodiment, a flip-chip light emitting diode (LED) assembly includes an LED comprising a light emitting layer disposed between layers of different conductivity types. In one embodiment, the layers comprise a group III-V compound. In another embodiment, the layers comprise a group II-VI compound. A via is formed in the LED through the light emitting layer. A channel is formed in the LED and extends from the via to a sidewall of the LED. In one embodiment, the channel has a width that is less than a width of the via.

In another embodiment, a plurality of vias is formed in the LED through the light emitting layer. A plurality of channels are formed in the LED and extends from each of the vias to another via, or to a sidewall of the LED. In one embodiment, the channels have a width that are less than the width of the vias they extend from.

A first interconnect is electrically coupled to a first layer of the LED having a first conductivity type and a second interconnect is electrically coupled to a second layer of the LED having a second conductivity type. A carrier is bonded to the LED. In one embodiment, the carrier is a submount. In another embodiment, the carrier is a handling substrate. In one embodiment, the submount having a third interconnect and a fourth interconnect is bonded to the first interconnect and the second interconnect, respectively. The bond forms an electric connection between the first and third interconnects, and the second and fourth interconnects.

In one embodiment, the flip-chip LED assembly is a traditional flip-chip structure having a substrate. In another embodiment, the flip-chip LED assembly is a thin-film flip-chip structure without a substrate. The embodiment may further include roughening a surface of the LED that is opposite the carrier.

In one embodiment, a method for forming a flip-chip LED assembly includes providing a substrate and forming an LED comprising a light emitting layer disposed between layers of different conductivity types on the substrate. In one embodiment, the layers comprise a group III-V compound. In another embodiment, the layers comprise a group II-VI compound.

In one embodiment, the method further includes forming a via in the LED through the light emitting layer. The embodiment further includes forming a channel in the LED and extending from the via to a sidewall of the LED. In another embodiment, the method further includes forming a plurality of vias in the LED. The embodiment further includes forming a plurality of channels in the LED, each of the channels extending from each of the plurality of vias to another via, or to a sidewall of the LED.

The method further includes forming a first interconnect electrically coupled to the a first layer of the LED having a first conductivity type, and a second interconnect electrically coupled to a second layer of the LED having a second conductivity type. The method further includes bonding a carrier to the LED. In one embodiment, the carrier is a submount. In another embodiment, the carrier is a handling wafer. In one embodiment, a submount having a third interconnect and a fourth interconnect is attached by bonding the third interconnect to the first interconnect, and the fourth interconnect to the second interconnect. In one embodiment, the bonding step is a eutectic bonding process. In another embodiment, the bonding step is an adhesive bonding process. In one embodiment, a vacuum is applied during the bonding step to extract air and bonding flux from the via(s).

In one embodiment, the method further includes removing the substrate. The embodiment may further include roughening a surface of the LED that is opposite the carrier.

### BRIEF DESCRIPTION OF THE FIGURES

FIG. 1A shows a plan view of a flip-chip LED with a plurality of vias formed in the surface of the LED.

FIG. 1B shows a cross-sectional view of a flip-chip LED assembly with a plurality of vias formed in the surface of the LED.

FIG. 2A shows a plan view of a flip-chip LED with a relief channel extending from a via to a sidewall of the LED, according to one embodiment of the invention.

FIG. 2B shows a cross-sectional view of the flip-chip LED of FIG. 2A.

FIG. 3A shows a plan view of a flip-chip LED with a plurality of relief channels, according to another embodiment of the invention.

FIGS. 3B-D shows cross-sectional views of the flip-chip LED of FIG. 3A.

FIGS. 4A-J shows a cross-sectional view of the manufacturing steps for producing a flip-chip LED assembly with a plurality of relief channels, according to another embodiment of the invention.

FIG. 5A shows a plan view of a wafer having a plurality of flip-chip LEDs with a plurality of vias formed in the surface of the LED, according to another embodiment of the invention.

FIG. 5B shows a cross-sectional view of a single flip-chip LED assembly after dicing the wafer of FIG. 5A.

FIGS. 6A-J shows a cross-sectional view of the manufacturing steps for producing a flip-chip LED assembly with a plurality of relief channels, according to another embodiment of the invention.

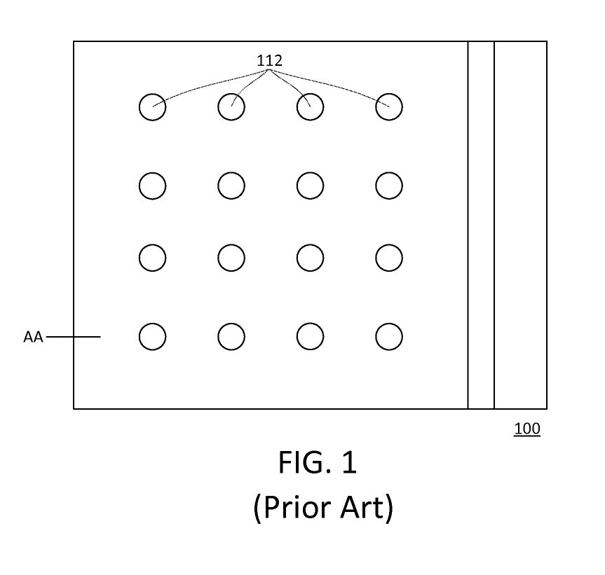

### DETAILED DESCRIPTION OF THE INVENTION

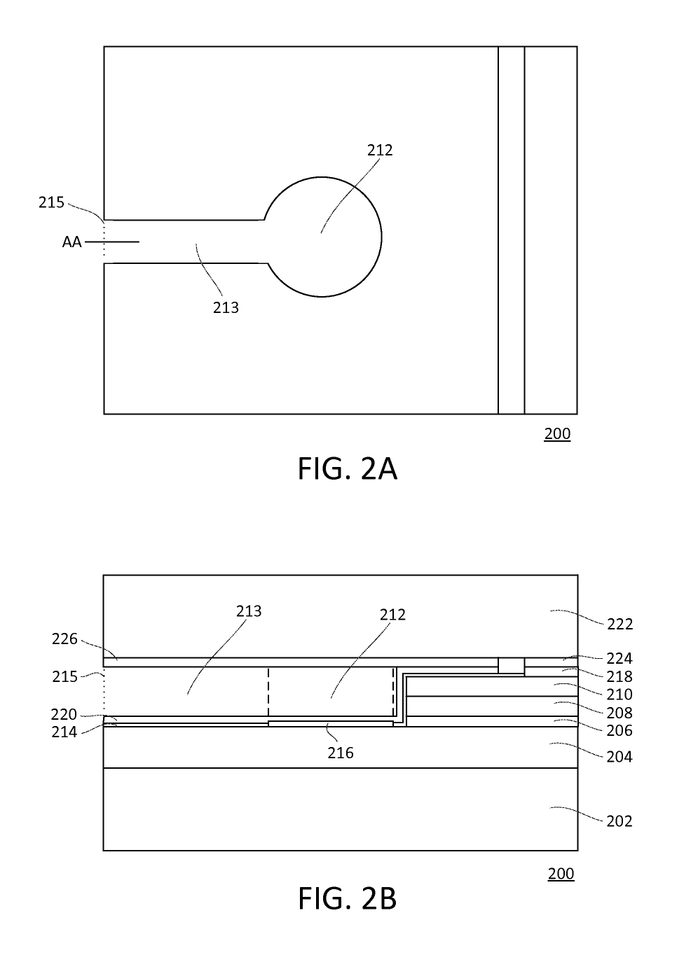

FIG. 2A shows a plan view of a flip-chip LED with a relief channel extending from a via to a sidewall of the LED, according to one embodiment of the invention. The plan view of the flip-chip LED 200 shown in FIG. 2A is shown without the carrier. In FIG. 2A, a via 212 is formed in the surface of the flip-chip LED 200. The via 212 extends down to the first semiconductor layer. A relief channel 213 is formed in the surface of the flip-chip LED 200, extending from via 212 to a sidewall 215 of the flip-chip LED 200. The relief channel 213 extends down to the first semiconductor layer of the flip-chip LED 200. The relief channel 213 has a width that is less than a width of the via 212. In one embodiment, the relief channel 213 has a width less than 60% of the width of the via 212. In another embodiment, the relief channel 213 has a width less than 80% of the width of the via 312.

FIG. 2B shows a cross-sectional view of the flip-chip LED of FIG. 2A. In FIG. 2B, the cross-sectional view is taken along the axis AA, shown in FIG. 2A. As shown in FIG. 2B, a semiconductor growth substrate 202 forms the base of the flip-chip LED 200. A first semiconductor layer 204 and a second semiconductor layer 208 are epitaxially grown on top of the semiconductor growth substrate 202. The junction of the first and second semiconductor layers 204 and 208 forms the light emitting layer 206 of the flip-chip LED 200.

A first electrode 210 is formed over the second semiconductor layer 208, and is electrically coupled to the second semiconductor layer 208. The via 212 and the relief channel 213 are etched into the surface of the flip-chip LED 200, through the first electrode 201, the second semiconductor layer 208, and the light emitting layer 206, down to the first semiconductor layer 204. In one embodiment, the via 212 and the relief channel 213 are etched into the first semiconductor layer 204. A passivation layer 214 is deposited over the flip-chip LED 200, covering the portions of the flip-chip LED 200 exposed by the via 212 and the relief channel 213, as well as the first electrode 210.

A portion of the passivation layer 214 at the bottom of the via 212 is etched to expose the first semiconductor layer 204. A second electrode 216 is formed over the exposed portion of the first semiconductor layer 204, and is electrically coupled to the first semiconductor layer 204. Another portion of the passivation layer is etched to expose part of the first electrode 210. A first interconnect 218 is formed over the exposed portion of the first electrode 210. The first interconnect 218 is electrically connected to the first electrode 210. A second interconnect 220 is deposited over the passivation layer 214 and the second electrode 216, and does not contact the first interconnect 218.

Using known bonding processes such as eutectic bonding, adhesive bonding, or soldering pastes, a carrier 222 having a third interconnect 224 and a fourth interconnect 226 is bonded to the flip-chip LED 200 to form the completed flip-chip assembly. In one embodiment, the carrier 222 is a submount package. The flip-chip LED 200 is electrically and thermally coupled to the carrier 222. During the bonding process, air and bonding flux that would have otherwise been trapped in the via 212 is allowed to escape through the relief channel 213, which acts as an open cavity, allowing for a better bond between the flip-chip LED 200 and the carrier 222. In one embodiment, a vacuum is applied during the bonding process to further improve the bond between the flip-chip LED 200 and the carrier 222 by forcibly extracting air and bonding flux from the via 212 through the relief channel 213.

By improving the quality of the bond between the flip-chip LED 200 and the carrier 222, the overall thermal and electrical performance of the flip-chip LED assembly is improved, and the flip-chip assembly has better manufacturing yield and overall reliability. Additionally, the relief channel 213 may extend into the first semiconductor layer 204 due to over-etch during the manufacturing process, in which case the sidewalls of the relief channel 213 may reflect some of the emitted light from the flip-chip LED 200, increasing the overall light output of the flip-chip LED assembly.

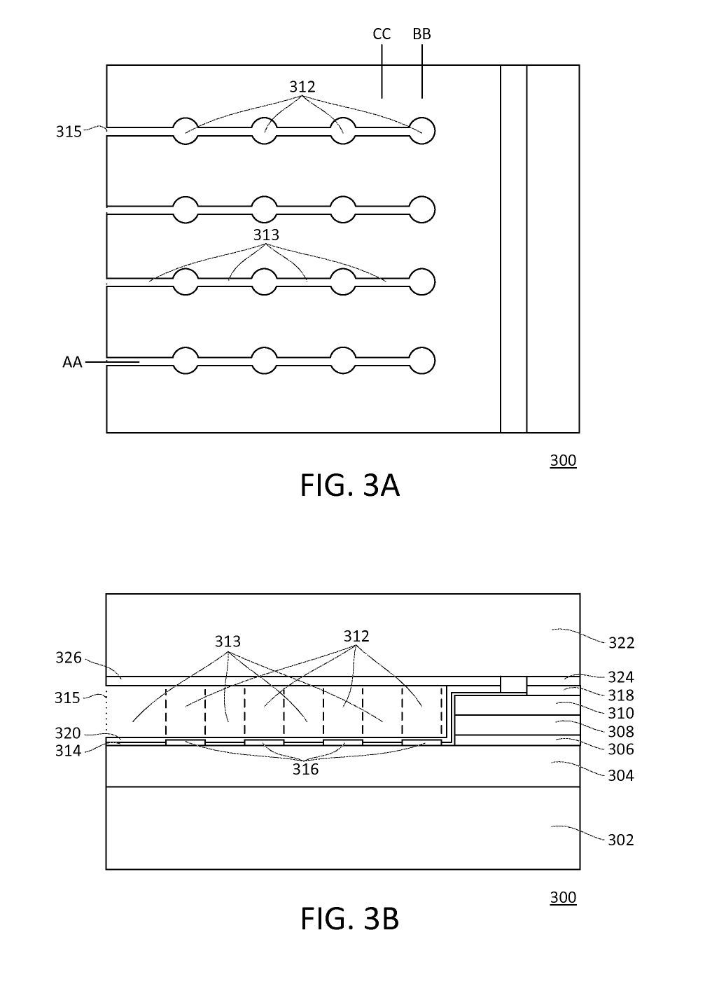

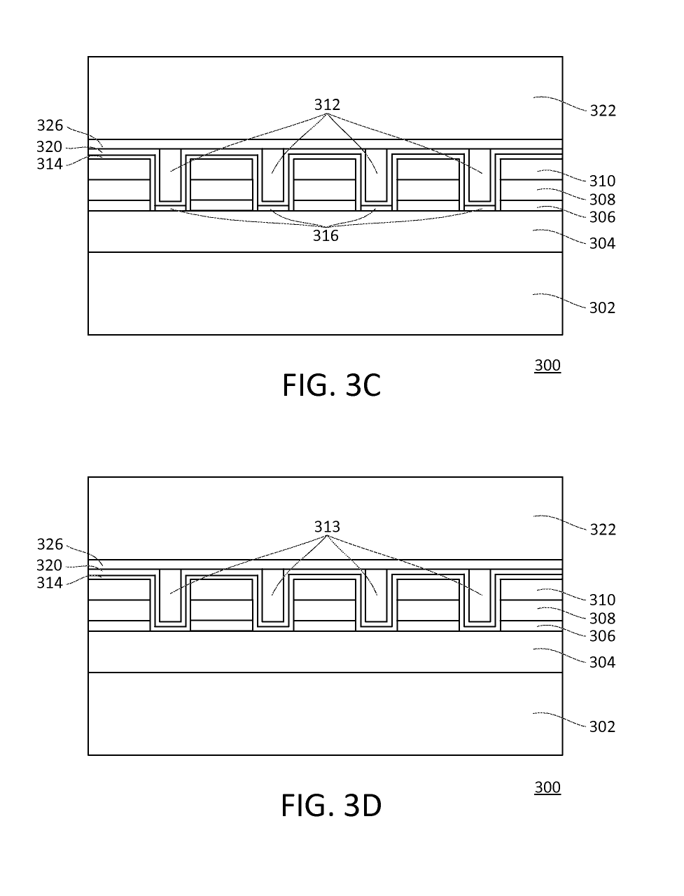

FIG. 3A shows a plan view of a flip-chip LED with a plurality of relief channels, according to another embodiment of the invention. In FIG. 3A, a plurality of vias 312 are formed in the surface of the flip-chip LED 300. Each of the vias 312 are only partially surrounded by the semiconductor layers of the flip-chip LED 300. Each of the plurality of vias 312 extend down to a first semiconductor layer. A plurality of relief channels 313 are formed in the surface of the flip-chip LED 300, extending from each of the vias 312 to another via, or to a sidewall 315 of the flip-chip LED 300. The relief channels 313 extend down to the first semiconductor layer of the flip-chip LED 300. The relief channels 313 have a width that is less than a width of the vias 312. In one embodiment, the relief channels 313 have a width less than 60% of the width of the vias 312. In another embodiment, the relief channels 313 have a width less than 80% of the width of the vias 312.

FIGS. 3B-D shows cross-sectional views of the flip-chip LED of FIG. 3A. In FIG. 3B, the cross-sectional view is taken along the axis AA, shown in FIG. 3A. The basic structure of the flip-chip LED assembly with a plurality of relief channels shown in FIG. 3B is substantially similar to that of the LED assembly with a single relief channel shown in FIG. 2B. First and second semiconductor layers 304 and 308 are epitaxially grown on semiconductor growth substrate 302. Light emitting layer 306 is sandwiched between the first and second semiconductor layers 304 and 308.

A first electrode 310 is electrically coupled to the second semiconductor layer 308 and subsequently the flip-chip LED 300 is etched to form a plurality of vias 312 and a plurality of relief channels 313. The vias are etched down to the first semiconductor layer 304, exposing a portion of the first semiconductor layer 304. The relief channels 313 are connected each of the plurality of vias 312 to another via, or to a sidewall 315 of the second semiconductor layer 308. The relief channels 313 are etched down to the first semiconductor layer 304. A passivation layer 314 is deposited over the flip-chip LED 300, and the portions of the passivation layer 314 covering the bottom of each of the plurality of vias 312 are etched to expose the first semiconductor layer 304.

A plurality of second electrodes 316 are electrically coupled to the first semiconductor layer 304 within each of the vias 312. A first and second interconnects 318 and 320 form an electric connection with the first and second electrodes 310 and 316, respectively. A carrier 322 with third and fourth interconnects 324 and 326 is bonded to the flip-chip LED 300 to form the flip-chip LED assembly, the third and fourth interconnects 324 and 326 electrically and thermally coupled to the first and second interconnects 318 and 320, respectively. In one embodiment, the carrier 322 is a submount package.

During the bonding process, the air and bonding flux may be expelled from the vias 312 to the outside of the flip-chip LED 300 through the relief channels 312, which acts as an open cavity. In one embodiment, a vacuum is applied during the bonding process to assist the removal of air and bonding flux from the vias 312. As previously mentioned, by removing the air and bonding flux from the vias 312, the quality of the bond formed between the flip-chip LED 300 and the carrier 322 is improved.

In FIG. 3C, the cross-sectional view is taken along the axis BB, shown in FIG. 3A. As shown in FIG. 3C, the plurality of vias 312 are completely covered by the carrier 322. Without the relief channels 313 extending from the vias 312 to the sidewall 315 of the second semiconductor layer 308, the air and bonding flux will not be able to escape from the vias 312, and will remain trapped inside the vias 312. In FIG. 3D, the cross-sectional view is taken along the axis CC, shown in FIG. 3A. In FIG. 3D, the plurality of relief channels 313 are covered by the carrier 322 as well. Because the relief channels 313 extend to the sidewall 315 of the second semiconductor layer 308, the air and the bonding flux that would otherwise be trapped inside the vias 312 are allowed to escape.

Compared to the flip-chip LED assembly shown in FIG. 2B, the flip-chip LED assembly shown in FIGS. 3B-D has improved lateral current spreading through the first and second semiconductor layers due to the second electrodes 316 at the bottom of each of the plurality of vias 312. As previously disclosed, the improved lateral current spreading of the device will reduce the amount of voltage required to drive the flip-chip LED 300 and improve light output efficiency. Additionally, the plurality of relief channels 313 may extend into the first semiconductor layer 304 due to over-etching during the manufacturing process, in which case the sidewalls of each of the relief channels 313 may reflect some of the emitted light from the flip-chip 300, further increasing the overall light output of the flip-chip LED assembly.

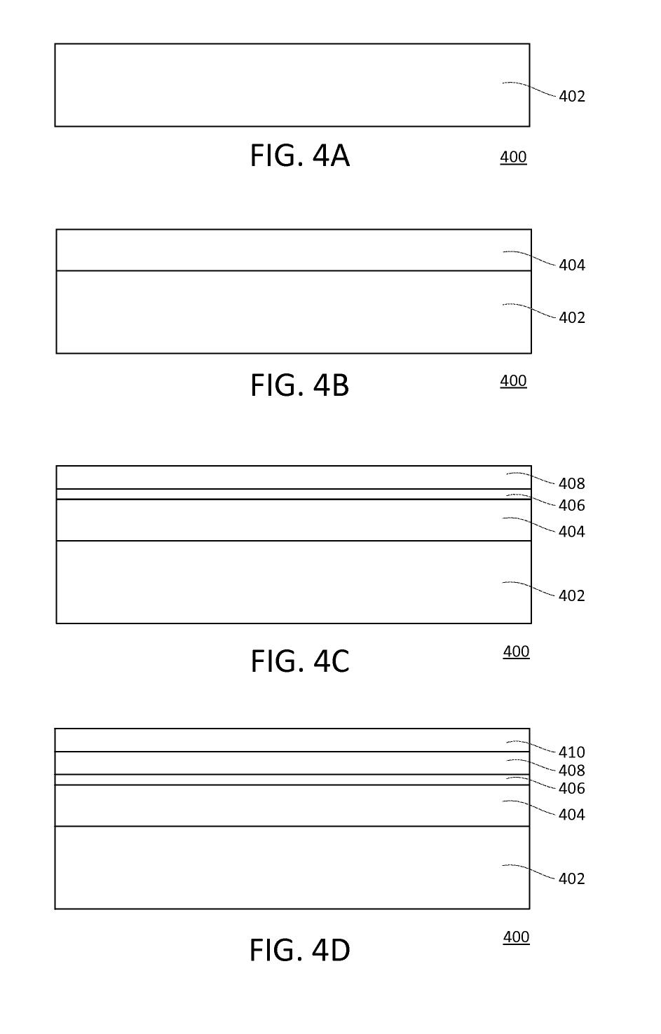

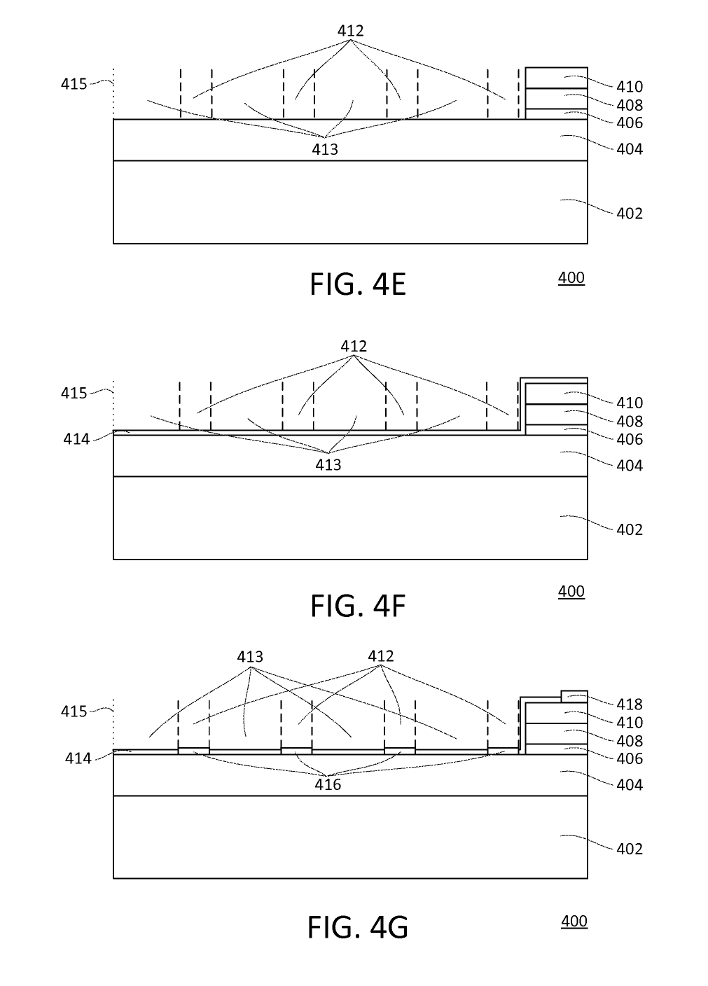

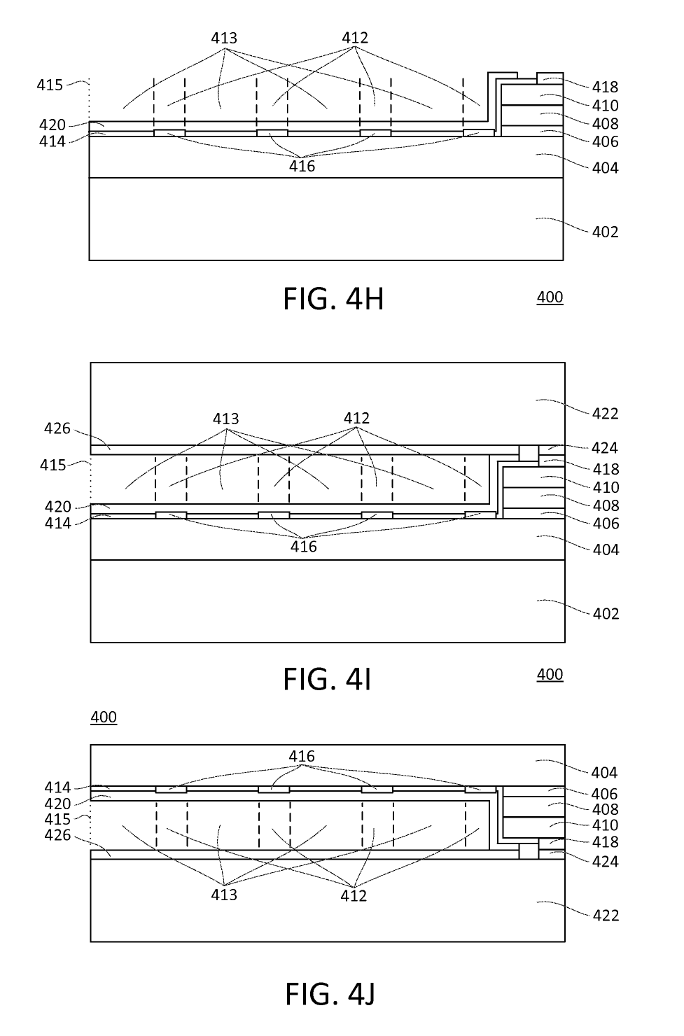

FIGS. 4A-J shows a cross-sectional view of the manufacturing steps for producing a flip-chip LED assembly with a plurality of relief channels, according to another embodiment of the invention. In FIG. 4A, the formation of flip-chip LED 400 begins by providing a semiconductor growth substrate 402. In one embodiment, the semiconductor growth substrate includes semiconductor materials such as sapphire (Al203), glass (SiO2), gallium nitride (GaN), silicon carbide (SiC), gallium phosphide (GaP), gallium arsenide (GaAs), and indium phosphide (InP).

In FIG. 4B, a first semiconductor layer 404 is epitaxially grown on top of the semiconductor growth substrate 402. In FIG. 4C, a second semiconductor layer 408 is grown on top of the first semiconductor layer 404. A light emitting layer 406 is formed at the junction between the first and the second semiconductor layers 404 and 408. In one embodiment, the first and second semiconductor layers 204 and 208 comprise a group III-V compound such as gallium nitride (GaN), gallium arsenide (GaAs), and indium phosphide (InP). In another embodiment, the first and second semiconductor layers 204 and 208 comprise a group II-VI compound such as zinc oxide (ZnO). In one embodiment, the first semiconductor layer 204 is a P-type, and the second semiconductor layer 208 is an N-type. In another embodiment, the first semiconductor layer 204 is an N-type, and the second semiconductor layer 208 is a P-type.

In FIG. 4D, a first electrode 410 is deposited over the second semiconductor layer 408, and is electrically coupled to the second semiconductor layer 408. In one embodiment, the first electrode 410 comprises an opaque and reflective material such as silver (Ag), aluminum (Al), or gold (Ag). The use of a reflective material for the first electrode 410 will allow for greater light output efficiency in the completed flip-chip LED assembly, as photons that are emitted downwards toward the submount package will be reflected and allowed to escape the device, rather than be absorbed by the submount package.

In FIG. 4E, a plurality of vias 412 and a plurality of relief channels 413 are formed by etching into the surface of the flip-chip LED 400, through the first electrode 410, the second semiconductor layer 408, and the light emitting layer 406, exposing the first semiconductor layer 404. In one embodiment, the vias 412 and relief channels 413 are formed by selectively growing the second semiconductor layer 408 and selectively depositing the first electrode 410 using known patterning and deposition processes. The plurality of relief channels 413 have a width that is less than the width of the vias 412 to minimize the loss of light emitting material of the flip-chip LED 400. In one embodiment, the relief channels 413 have a width less than 80% of the width of the vias 412. In another embodiment, the relief channels 313 have a width less than 60% of the width of the vias 412.

In FIG. 4F, a passivation layer 414 is deposited over the surface of the flip-chip LED 400, covering the exposed portions of the first semiconductor layer 404, the light emitting layer 406, the second semiconductor layer 408, and the first electrode 410. The passivation layer 414 may comprise any insulating material. In one embodiment, the passivation layer 414 includes semiconductor materials such as dielectric materials (SiOx and SiNx), spin-on-glass (SOG), or polymers.

In FIG. 4G, a first interconnect 418 is electrically coupled to the first electrode 410, and a plurality of second electrodes 416 are electrically coupled to the first semiconductor layer 404. The first interconnect 418 is formed by etching away a portion of the passivation layer 414 covering the first electrode 410. The first interconnect 418 is then deposited over the exposed portion of the first electrode 410. In a similar manner, the plurality of second electrodes 416 are formed by etching away portions of the passivation layer 414 at the bottom of each of the vias 412, exposing the first semiconductor layer 404. The second electrodes 416 are then deposited at the bottom of each of the vias 412 and are electrically coupled to the first semiconductor layer 404.

In FIG. 4H, a second interconnect 420 is deposited over the surface of the flip-chip LED 400, covering the passivation layer 414 and each of the second electrodes 416. The second interconnect 420 is electrically coupled to the second electrodes 416. The second interconnect 420 is not deposited over the first interconnect 418, and does not contact the first interconnect 418. Any contact between the first and the second interconnects 418 and 420 will cause an electrical short, and will damage flip-chip LED 400.

In FIG. 4I, a carrier 422 having a third interconnect 424 and a fourth interconnect 426 is bonded to the flip-chip LED 400. In one embodiment, the carrier is a submount package. The bonding process forms an electric connection between the first and third interconnects 418 and 424, and the second and fourth interconnects 420 and 426, thereby electrically and thermally coupling the flip-chip LED 400 to the carrier 422. In one embodiment, the carrier 422 is bonded to the flip-chip LED 400 by a eutectic bonding process. In another embodiment, the carrier 422 is bonded to the flip-chip LED 400 by an adhesive bonding process. In one embodiment, a vacuum is applied during the bonding process to forcibly extract air and bonding flux from the vias 412 through the relief channels 413.

The flip-chip LED assembly shown in FIG. 4I is fully functional, and is ready to be packaged for its final application. Optionally, in FIG. 4J, the semiconductor growth substrate 402 is removed and the exposed surface of the first semiconductor layer 404 is roughened to form a thin-film flip-chip LED assembly. As previously mentioned, the thin-film flip-chip LED has greater light output efficiency than a traditional flip-chip LED.

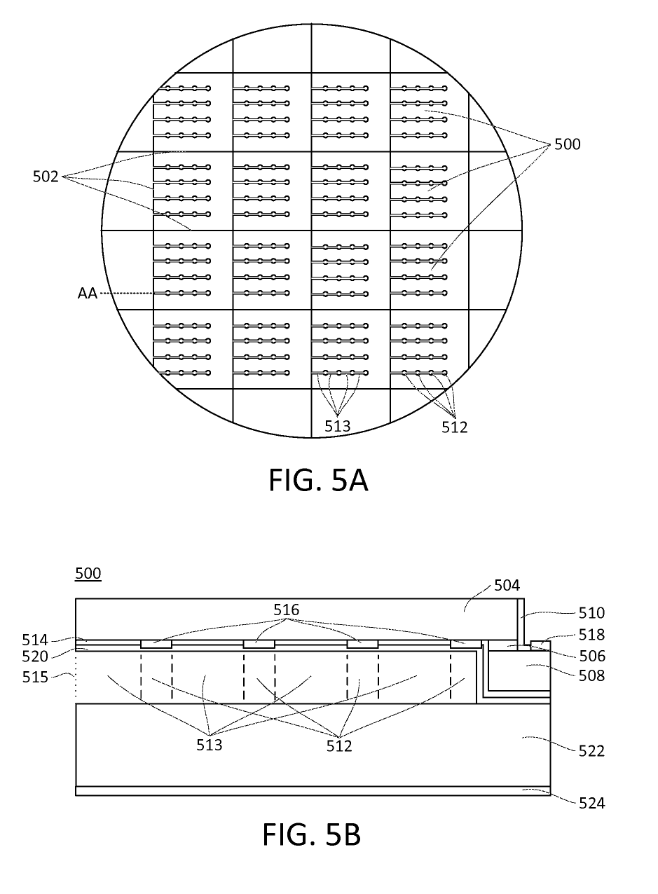

FIG. 5A shows a plan view of a wafer having a plurality of flip-chip LEDs with a plurality of vias formed in the surface of the LED, according to another embodiment of the invention.

FIG. 5A shows a plan view of a wafer having a plurality of flip-chip LEDs with a plurality of vias formed in the surface of the LED, according to another embodiment of the invention. In FIG. 5A, a plurality of flip-chip LEDs 500 are formed on a wafer. Each of the flip-chip LEDs 500 have a plurality of vias 512 and a plurality of relief channels 513 formed in the surface of the flip-chip LEDs 500. Each of the relief channels 513 extend from each of the vias 512 to another via, or to a sidewall of the flip-chip LEDs 500. The relief channels 513 have a width less than a width of the vias 512. In one embodiment, the relief channels 513 have a width less than 60% of the width of the vias 512. In another embodiment, the relief channels 513 have a width less than 80% of the width of the vias 512. Each of the flip-chip LEDs 500 are separated by dicing streets 502, which run along the edges of each of the flip-chip LEDs 500. In one embodiment, dicing streets 502 comprise a trench separating adjacent flip-chip LEDs 500.

FIG. 5B shows a cross-sectional view of a single flip-chip LED assembly after dicing the wafer of FIG. 5A. In FIG. 5B, the cross-sectional view is taken along the axis AA, shown in FIG. 5A. The basic structure of the flip-chip LED assembly with a plurality of relief channels shown in FIG. 5B is substantially similar to that of the LED assembly with a plurality of relief channels shown in FIG. 3B. First and second semiconductor layers 504 and 508 are epitaxially grown on a semiconductor growth substrate (not shown). Light emitting layer 506 is sandwiched between the first and second semiconductor layers 504 and 508.

The flip-chip LED 500 is etched to form a plurality of vias 512 and a plurality of relief channels 513. The vias are etched down to the first semiconductor layer 504, exposing a portion of the first semiconductor layer 504. The relief channels 513 connect each of the plurality of vias 512 to another via, or to a sidewall 515 of the second semiconductor layer 508. The relief channels 513 are etched down to the first semiconductor layer 504. A passivation layer 514 is deposited over flip-chip LED 500, and the portions of the passivation layer 514 covering the bottom of each of the plurality of vias 513 are etched to expose the first semiconductor layer 504.

A plurality of first electrodes 516 are electrically coupled to the first semiconductor layer 504 within each of the vias 512. An intervening layer 520 forms an electric contact with the first electrodes 516. In one embodiment, the intervening layer is a metal bonding layer deposited over the surface of the flip-chip LED 500 prior to wafer bonding. A carrier 522 is bonded to the flip-chip LED 500 to form the flip-chip LED assembly, the carrier 522 electrically and thermally coupled to the flip-Chip LED 500. In one embodiment, the carrier 522 is a handling substrate.

After carrier 522 is bonded to the flip-chip LED 500, the growth substrate is removed, exposing the first semiconductor layer 504. In one embodiment, the exposed surface of the first semiconductor layer 504 is roughened. A portion of the first semiconductor layer 504 and the light emitting layer 506 are etched to expose the second semiconductor layer 508. A second electrode 518 is electrically coupled to the second semiconductor layer 508, and an insulating layer 510 is deposited between the second electrode 518 and the first semiconductor layer 504 and the light emitting layer 506. A third electrode 524 is deposited on a surface of the carrier 522 opposite the bonded flip-chip LED 500. The third electrode 524 is electrically coupled to the carrier 522. The flip-chip LED assembly shown in FIG. 5B is then diced along the dicing streets 502 shown in FIG. 5A, and packaged for its final application.

During the bonding process, the air and bonding flux may be expelled from the vias 512 to the outside of each of the flip-chip LEDs 500 through the relief channels 512 and through the dicing streets 502. In one embodiment, a vacuum is applied during the bonding process to assist the removal of air and bonding flux from the vias 512. As previously mentioned, by removing the air and bonding flux from the vias 512, the quality of the bond formed between each of the flip-chip LEDs 500 and the carrier 522 is improved.

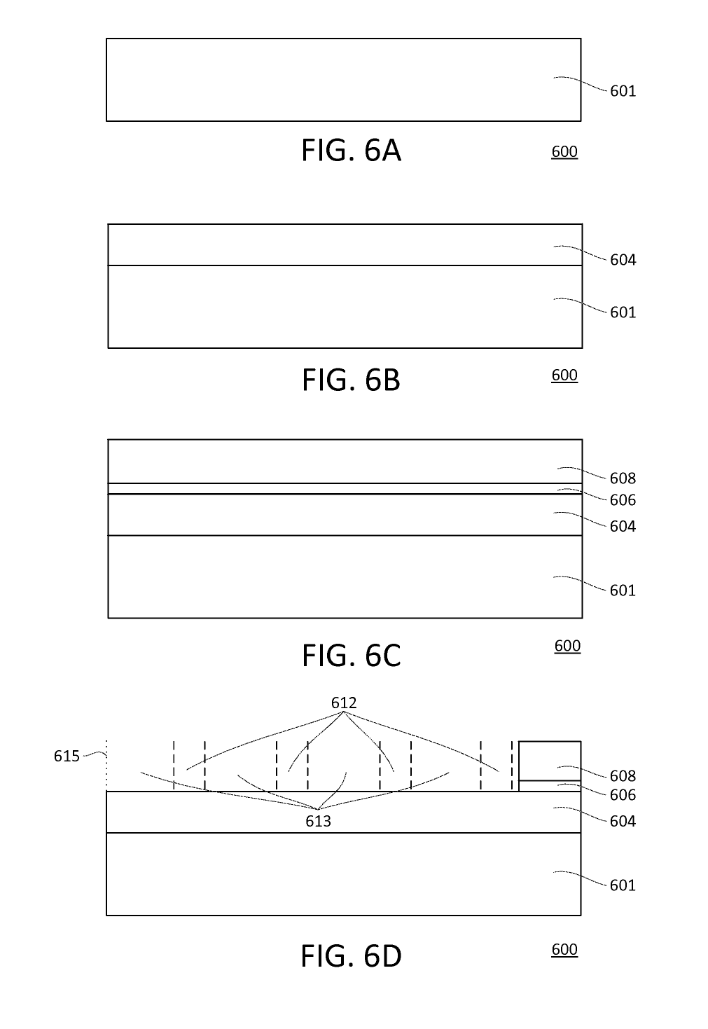

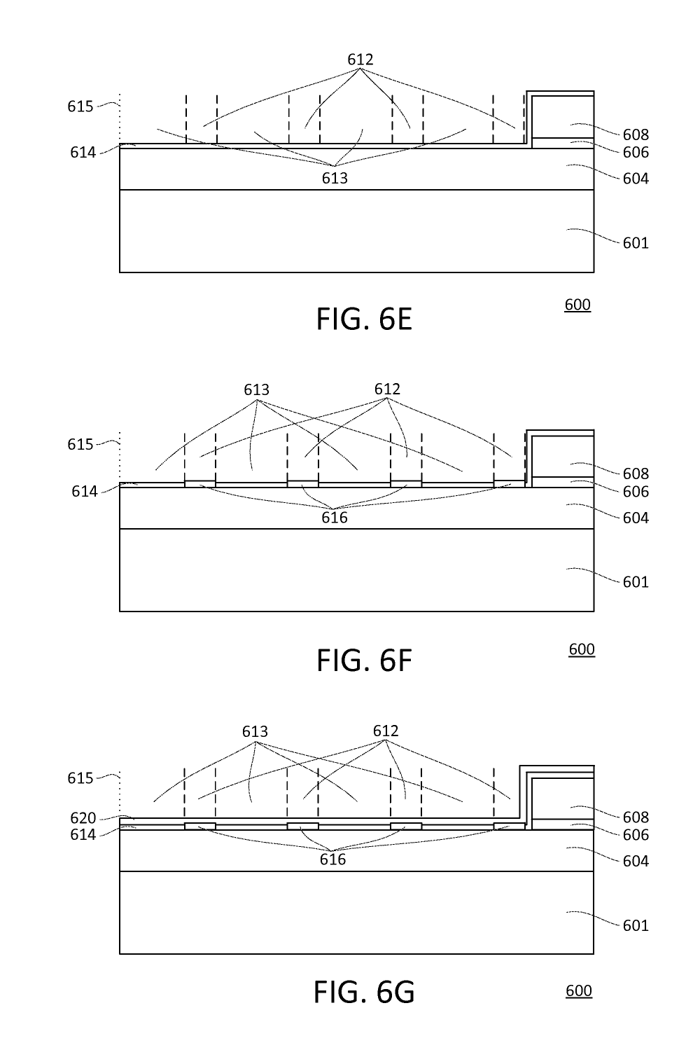

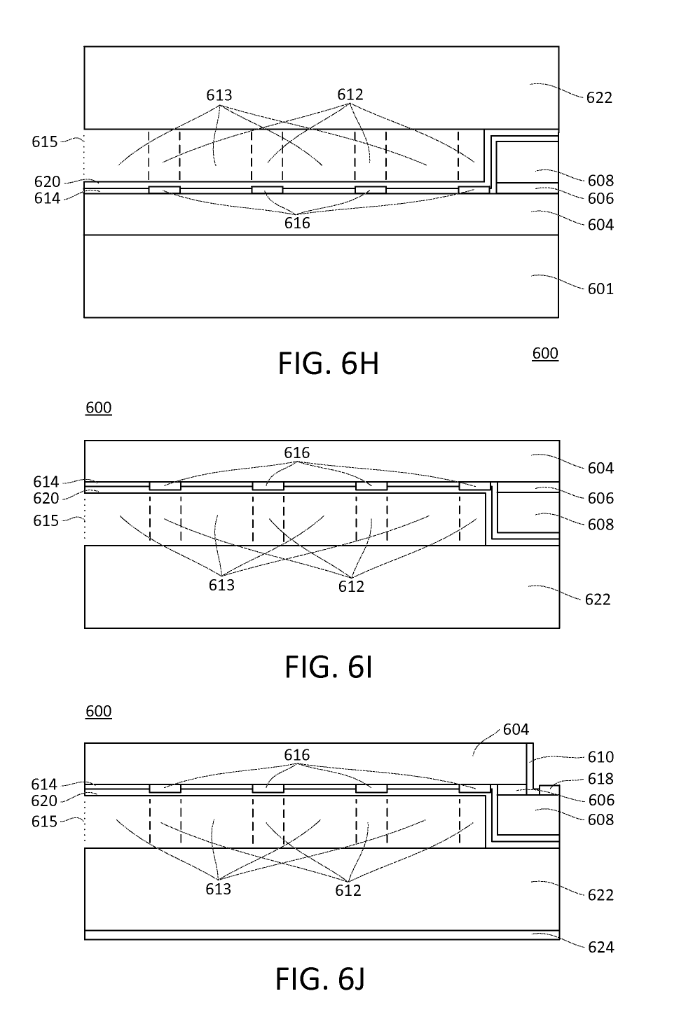

FIGS. 6A-J shows a cross-sectional view of the manufacturing steps for producing a flip-chip LED assembly with a plurality of relief channels, according to another embodiment of the invention. In FIG. 6A, the formation of flip-chip LED 600 begins by providing a semiconductor growth substrate 601. In one embodiment, the semiconductor substrate includes semiconductor materials such as silicon (Si). In FIG. 6B, a first semiconductor layer 604 is grown on top of the semiconductor growth substrate 601. In FIG. 6C, a second semiconductor 608 is grown on top of the first semiconductor layer 604. A light emitting layer 606 is formed at the junction between the first and the second semiconductor layers 604 and 608. In one embodiment, the first and second semiconductor layers 604 and 608 comprise a group III-V compound such as gallium nitride (GaN), gallium arsenide (GaAs), and indium phosphide (InP). In another embodiment, the first and second semiconductor layers 604 and 608 comprise a group II-VI compound such as zinc oxide (ZnO). In one embodiment, the first semiconductor layer 604 is a P-type, and the second semiconductor layer 608 is an N-type. In another embodiment, the first semiconductor layer 604 is an N-type, and the second semiconductor layer 608 is a P-type.

In FIG. 6D, a plurality of vias 612 and a plurality of relief channels 613 are formed by etching into the surface of the flip-chip LED 400 down to the first semiconductor layer 604, exposing the first semiconductor layer 604. In one embodiment, the vias 612 and relief channels 613 are formed by selectively growing the second semiconductor layer 608 using known patterning and deposition processes. In one embodiment, the relief channels 613 have a width less than 80% of the width of the vias 612. In another embodiment, the relief channels 613 have a width less than 60% of the width of the vias 612.

In FIG. 6E, a passivation layer 614 is deposited over the surface of the flip-chip LED 600, covering the exposed portions of the first semiconductor layer 604, the light emitting layer 606, and the second semiconductor layer 608. The passivation layer 614 may comprise any insulating material. In one embodiment, the passivation layer 614 includes semiconductor materials such as dielectric materials (SiOx and SiNx), spin-on-glass (SOG), or polymers. In FIG. 6F, a plurality of first electrodes 616 are formed by etching away portions of the passivation layer 614 at the bottom of each of the vias 612, exposing the first semiconductor layer 604. The first electrodes 616 are then deposited at the bottom of each of the vias 612 and are electrically coupled to the first semiconductor layer 604.

In FIG. 6G, an intervening layer 620 is deposited over the surface of the flip-chip LED 600, covering the passivation layer 614 and each of the first electrodes 616. In one embodiment, the intervening layer 620 is a metal bonding layer. In FIG. 6H, a carrier 622 is bonded to the flip-chip LED 600. In one embodiment, the carrier 622 is a handling substrate. In one embodiment, the carrier 622 is bonded to the flip-chip LED 600 by a eutectic bonding process. In another embodiment, the carrier 622 is bonded to the flip-chip LED 600 by an intermetallic bonding process. In yet another embodiment, the carrier 622 is bonded to the flip-chip LED 600 by an adhesive bonding process. In one embodiment, a vacuum is applied during the bonding process to forcibly extract air and bonding flux from the vias 612 through the relief channels 613. In one embodiment, the carrier 622 is electrically and thermally coupled to the flip-chip LED.

In FIG. 6I, the growth substrate 601 is removed, exposing a surface of the first semiconductor layer 604. In one embodiment, the growth substrate 601 is removed by laser lift-off (LLO). In another embodiment, the growth substrate 601 is removed by mechanical grinding. In yet another embodiment, the growth substrate 601 is removed by chemical etching. In yet another embodiment, the growth substrate 601 is removed by a combination of known techniques. In one embodiment, the exposed surface of the first semiconductor layer 604 is roughened.

In FIG. 6J, a portion of the first semiconductor layer 604 and the light emitting layer 606 is etched to expose a portion of the second semiconductor layer 608. A second electrode 618 is electrically coupled to the second semiconductor layer 608 and an insulating layer 610 is deposited between the second electrode 618 and the first semiconductor layer 604 and the light emitting layer 606. Optionally, a third electrode 624 is electrically coupled to the carrier 622 on a surface opposite the flip-chip LED 600. In one embodiment, the third electrode 624 is electrically coupled to the intervening layer 620.

Other objects, advantages and embodiments of the various aspects of the present invention will be apparent to those who are skilled in the field of the invention and are within the scope of the description and the accompanying Figures. For example, but without limitation, structural or functional elements might be rearranged, or method steps reordered, consistent with the present invention. Similarly, principles according to the present invention, and methods and systems that embody them, could be applied to other examples, which, even if not specifically described here in detail, would nevertheless be within the scope of the present invention.

1. A light emitting diode (LED) assembly comprising:
an LED comprising:
a light emitting layer disposed between layers of different conductivity types;
a via formed in the LED through the light emitting layer;
a carrier bonded to the LED; and
a channel formed in the LED extending from the via to a sidewall of the LED, the channel exposed at an upper surface of the LED.

2. The LED assembly of claim 1 wherein the carrier is a submount electrically coupled to the LED, forming an electric contact therebetween.

3. The LED assembly of claim 2 further comprising:
a first interconnect electrically coupled to a first layer of the LED having a first conductivity type;
a second interconnect electrically coupled to a second layer of the LED having a second conductivity type;
a third interconnect and a fourth interconnect attached to the submount; and
wherein the first interconnect forms an electric contact with the third interconnect, and the second interconnect forms an electric contact with the fourth interconnect.

4. The LED assembly of claim 1 wherein the carrier is a handling substrate.

5. The LED assembly of claim 4 further comprising:
a first interconnect electrically coupled to a first layer of the LED having a first conductivity type; and
a second interconnect electrically coupled to a second layer of the LED having a second conductivity type.

6. The LED assembly of claim 3 wherein a surface of the first layer opposite the second layer is roughened.

7. The LED assembly of claim 1 further comprising a substrate attached to a surface of the LED opposite the carrier.

8. The LED assembly of claim 1 further comprising:
a plurality of vias formed in LED through the light emitting layer; and
a plurality of channels formed in LED extending from the plurality of vias to another via, or to a sidewall of the LED, each of the plurality of channels exposed at an upper surface of the LED to the carrier.

9. The LED assembly of claim 1 wherein the channel has a width less than a width of the via.

10. (canceled)

11. (canceled)

12. (canceled)

13. (canceled)

14. (canceled)

15. (canceled)

16. (canceled)

17. (canceled)

18. (canceled)

19. (canceled)

20. (canceled)

21. The LED assembly of claim 1, wherein the channel comprises an open cavity.

22. The LED assembly of claim 1, wherein the channel is open at the sidewall of the LED.

23. The LED assembly of claim 1, wherein the channel is open at the upper surface of the LED.
